(19) United States
(12) Patent Application Publication
(10) Pub. No.: US 2014/0085213 A1
(43) Pub. Date: Mar. 27, 2014

(54) Force Sensing Using Bottom-Side Force Map

(71) Applicant: APPLE INC., Cupertino, CA (US)

(72) Inventors: Brian Q. Huppi, San Francisco, CA (US); Omar Sze Leung, Palo Alto, CA (US); Craig Christopher Leong, San Jose, CA (US); Paul Stephen Drzaic, Morgan Hill, CA (US)

(73) Assignee: Apple Inc., Cupertino, CA (US)

(21) Appl. No.: 13/624,858

(22) Filed: Sep. 21, 2012

(51) Int. Cl. H03K 17/975; G06F 3/041; G09G 3/32; G01L 1/00

(52) U.S. Cl. 345/173; 73/862.541; 200/600; 345/82

(57) ABSTRACT

A force sensor incorporated into a touch device, measuring deflection in a device stack, including compressible elements disposed between the device stack and the frame element. When the device stack is deformed, applied force is measured using the compressible elements, using capacitive sensing or strain measurements. The force sensitive sensor provides an applied force image for the touch device's surface. The applied force location [X, Y] can be determined from measures of cover glass tilt, force at particular points, and capacitive sensing of touch location.

### BACKGROUND

1. Field of the Disclosure

This application generally relates to force sensing in a touch device, and related matters.

2. Background of the Disclosure

Touch devices generally provide for identification of positions where the user touches the device, including movement, gestures, and other effects of position detection. For a first example, touch devices can provide information to a computing system regarding user interaction with a graphical user interface (GUI), such as pointing to elements, reorienting or repositioning those elements, editing or typing, and other GUI features. For a second example, touch devices can provide information to a computing system suitable for a user to interact with an application program, such as relating to input or manipulation of animation, photographs, pictures, slide presentations, sound, text, other audiovisual elements, and otherwise.

It sometimes occurs that, when interfacing with a GUI, or with an application program, it would be advantageous for the user to be able to indicate an amount of force applied when manipulating, moving, pointing to, touching, or otherwise interacting with, a touch device. For example, it might be advantageous for the user to be able to manipulate a screen element or other object in a first way with a relatively lighter touch, or in a second way with a relatively more forceful or sharper touch. In one such case, a it might be advantageous if the user could move a screen element or other object with a relatively lighter touch, while the user could alternatively invoke or select that same screen element or other object with a relatively more forceful or sharper touch.

Each of these examples, as well as other possible considerations, can cause one or more difficulties for the touch device, at least in that inability to determine an amount of force applied by the user when contacting the touch device might cause a GUI or an application program to be unable to provide functions that would be advantageous. When such functions are called for, inability to provide those functions may subject the touch device to lesser capabilities, to the possible detriment of the effectiveness and value of the touch device. On the other hand, having the ability to provide those functions might provide the touch device with greater capabilities, to the possible advantage of the effectiveness and value of the touch device.

### BRIEF SUMMARY OF THE DISCLOSURE

This application provides techniques, including circuits and designs, which can determine amounts of force applied, and changes in amounts of force applied, by the user when contacting a touch device (such as a touch pad or touch display). These techniques can be incorporated into devices using touch recognition, touch elements of a GUI, and touch input or manipulation in an application program. This application also provides techniques, including devices that apply those techniques, which can determine amounts of force applied, and changes in amounts of force applied, by the user when contacting a touch device, and in response thereto, provide additional functions available to a user of a touch device.

In one embodiment, techniques can include providing a force sensitive sensor incorporated into a touch device, and measuring deflection in a device stack, the device stack including a frame element, the force sensitive sensor, a set of display elements, and a cover glass (CG) element. The CG may be glass, chemically strengthened glass, sapphire, polycarbonate or any other suitable material. For example, the force sensitive sensor can include a compressible layer, or a set of compressible elements, disposed between a set of organic light emitting diode (OLED) plastic display elements and the frame element. When the OLED display elements are substantially flexible, it can be deformed in response to applied force. This has the effect that amounts of force can be measured with respect to deformation of the device stack above the compressible layer or compressible elements, such as using localized capacitive sensing, localized measurements of strain due to applied force, or otherwise. In response to localized measurements of amounts of force, the force sensitive sensor can provide an image of applied force applicable to the entire surface, or a portion thereof, of the touch device. In alternative embodiments, such techniques can include, alternatively or in conjunction, any flexible display technology, such as any reflective or other display in which the sensor could be placed behind the display. For example, such techniques can include, without limitation, one or more of: flexible electrophoretic displays, liquid crystal displays, polymer dispersed liquid crystal displays, polymer network liquid crystal displays, microencapsulated cholesteric liquid crystal displays, electrochromic displays, electrofluidic displays, electrokinetic displays, or otherwise.

In one embodiment, the compressible layer, or the set of compressible elements, can include capacitive sensing, by which a measurement of applied force can be determined. The location of the applied force can be determined in response to a measure of tilt on a cover glass (CG) with respect to one or more axes. For example, a force applied at a particular point [X, Y] can be determined in response to measurements of applied force at edges of the cover glass, and possibly at other locations in between the point [X, Y] and the edges of the cover glass. In alternative embodiments, capacitive sensing can determine a touch location, while measurements of applied force can be used in combination or conjunction with the touch location to determine a measure of applied force at the particular point where the touch occurs.

In one embodiment, capacitive sensing can be determined using a first layer of indium tin oxide (ITO) and a second layer of ITO as a dual-layer capacitive element (sometimes collectively referred to as DITO). In alternative embodiments, capacitive sensing can be determined using a first layer of ITO as a self-capacitive element, with respect to a substantially conductive (such as metallic) second layer. When applied force occurs at a particular point [X, Y] on the cover glass, the device stack can be deformed near and around that point, with the effect that the capacitive sensor measures a change in capacitance at one or more points near and around that point. For example, the capacitive sensor can include a set of rows and columns, one set (such as the rows) providing a driver for voltage along selected ones of rows, and one set (such as the columns) providing a drain for voltage along selected ones of columns. This has the effect that the capacitive sensor can determine one or more locations where changes in capacitance occur. The touch device can determine, in response to the change in capacitance, an amount of applied force. For example, the touch device can use a processor or other computing device, with the effect of determining a location and amount of applied force.

In one embodiment, the compressible layer, or the set of compressible elements, can include a capacitive layer disposed between the first layer of ITO and the second layer of ITO can include an air gap, with the effect that capacitance is measured across the air gap. In one embodiment, the capacitive layer disposed between the first layer of ITO and the second layer of ITO can include a layer of pressure-sensitive adhesive (PSA), which can be either substantially transparent or translucent (if located above the OLED layer), or can alternatively be opaque or otherwise light-absorbent (if located below the OLED layer). In either such case, the capacitive layer has the effect of not interfering with operation of the display. Further, materials other than ITO may be used, such as silver nanowire and other transparent (or near-transparent) electrically conductive electrodes.

In one embodiment, the compressible layer, or the set of compressible elements, can include an elastic element, including one or more of: a liquid including a set of open cells, a “moth eye” structure (such as including nanostructured pyramids, pillars, cones, or other elongated nanoscale elements), a nanofoam structure, a silicone rubber structure, or otherwise. For example, the compressible layer could include one or more of: a set of individual relatively open elements; a set of relatively compressible solid elements; a network of both open areas and solid elements, such as an interpenetrating network thereof; a combination or conjunction of regions which include relatively open areas and regions which include relatively solid elements; or otherwise.

For a first example, the compressible layer can include a set of pyramidal structures, such as individual pyramids or inverted pyramids, or both interspersed pyramids and inverted pyramids, with the effect of providing a layer that is both compressible and which has a substantially known capacitive response to deformation. For a second example, the compressible layer can include a set of extended pyramidal structures (alternatively, also with a set of inverted extended pyramidal structures), such as having a pyramidal cross-section in a first direction and being extended lengthwise in a second direction. This has the effect of providing a layer that is both compressible and which has a substantially linear capacitive response to deformation. For a third example, the compressible layer can include a double “moth eye” structure, such as in which both moth eye structures and inverted moth eye structures are interspersed similar to stalactites and stalagmites, with the effect of providing a layer that is both compressible and transparent. For a fourth example, the compressible layer can include an array of strain gauges, such as an array of springs or other elements whose resistance alters in response to strain. After reading this application, those skilled in the art would recognize that these possibilities are exemplary, and are not intended to be limiting in any way. Moreover, those skilled in the art would recognize that a combination or conjunction of such examples would be workable, and are within the scope and spirit of the invention. For example, one embodiment could use a first such example in a first portion of the compressible layer, a second such example in a second portion of the compressible layer, or an interpenetrating network of multiple examples in at least a third portion of the compressible layer.

While multiple embodiments are disclosed, including variations thereof, still other embodiments of the present disclosure will become apparent to those skilled in the art from the following detailed description, which shows and describes illustrative embodiments of the disclosure. As will be realized, the disclosure is capable of modifications in various obvious aspects, all without departing from the spirit and scope of the present disclosure. Accordingly, the drawings and detailed description are to be regarded as illustrative in nature and not restrictive.

### BRIEF DESCRIPTION OF THE FIGURES

While the specification concludes with claims particularly pointing out and distinctly claiming the subject matter that is regarded as forming the present disclosure, it is believed that the disclosure will be better understood from the following description taken in conjunction with the accompanying Figures, in which:

FIG. 1 shows a conceptual drawing of communication between a touch I/O device and a computing system.

FIG. 2 shows a conceptual drawing of a system including a force sensitive touch device.

FIG. 3 shows a conceptual drawing of a force sensor including a dual-layer cover glass.

FIGS. 4A-D show conceptual drawings of force sensitive structures.

### DETAILED DESCRIPTION

### Terminology

The following terminology is exemplary, and not intended to be limiting in any way.

The text “applied force”, and variants thereof, generally refers to a degree or measure of an amount of force being applied to a device. The degree or measure of applied force need not have any particular scale. For example, the measure of applied force can be linear, logarithmic, or otherwise nonlinear, and can be adjusted periodically (or otherwise, such as aperiodically, or otherwise from time to time) in response to one or more factors, either relating to applied force, location of touch, time, or otherwise.

The text “force sensing element”, and variants thereof, generally refers to one or more data elements of any kind, including information sensed with respect to applied force, whether at individual locations or otherwise. For example and without limitation, a force sensing element can include data or other information with respect to a relatively small region of where a user is forcibly contacting a device.

The text “touch sensing element”, and variants thereof, generally refers to one or more data elements of any kind, including information sensed with respect to individual locations. For example and without limitation, a touch sensing element can include data or other information with respect to a relatively small region of where a user is contacting a touch device.

The text “user's finger”, and variants thereof, generally refers to a user's finger, or other body part, or a stylus or other device, such as when used by a user to apply force to a touch device, or to touch a touch device. For example and without limitation, a “user's finger” can include any part of the user's finger, the user's hand, a covering on the user's finger, a soft or hard stylus, a light pen or air brush, or any other device used for pointing, touching, or applying force to, a touch device or a surface thereof.

After reading this application, those skilled in the art would recognize that these statements of terminology would be applicable to techniques, methods, physical elements, and systems (whether currently known or otherwise), including extensions thereof inferred or inferable by those skilled in the art after reading this application.

Force Sensitive Device and System

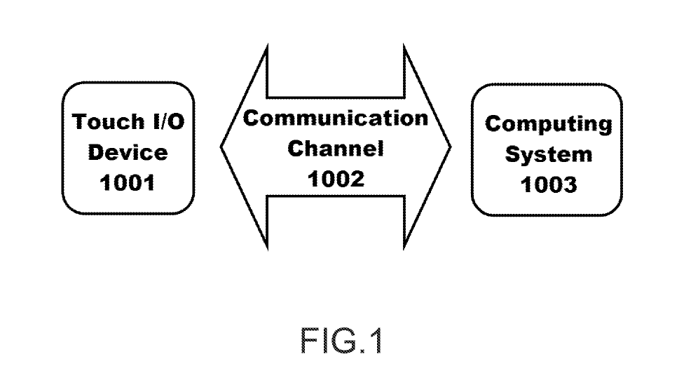

FIG. 1 shows a conceptual drawing of communication between a touch I/O device and a computing system.

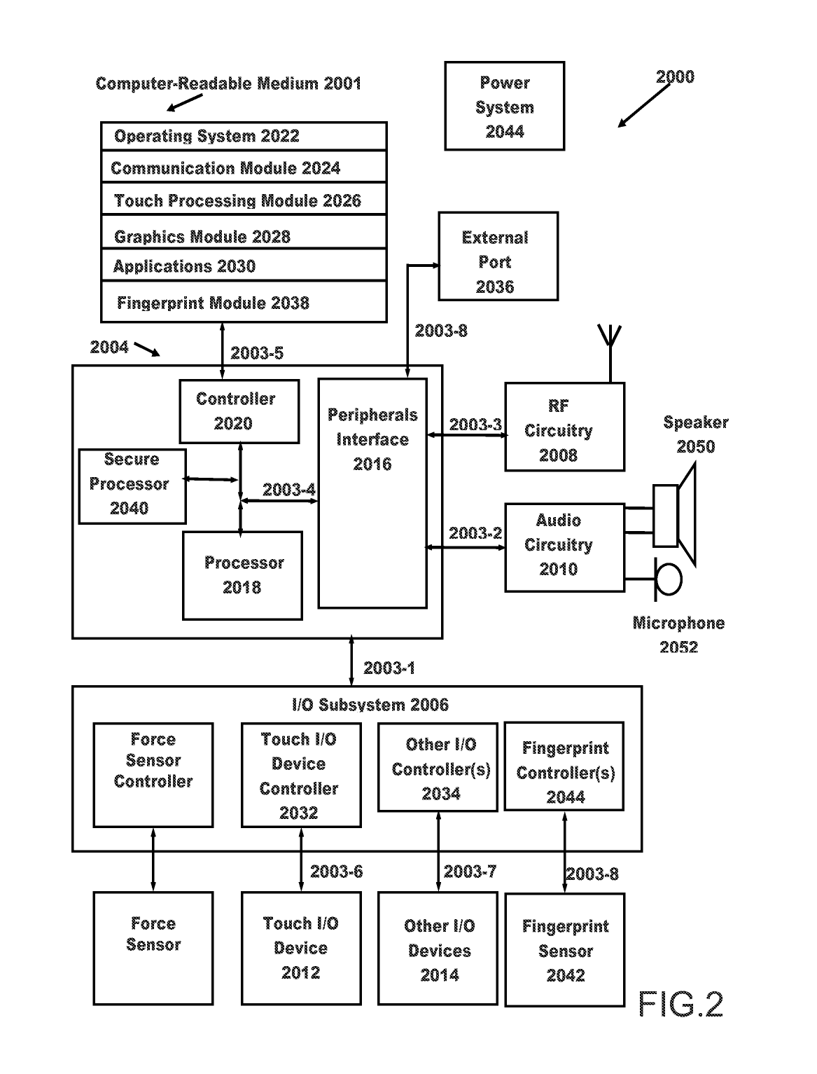

FIG. 2 shows a conceptual drawing of a system including a force sensitive touch device.

Described embodiments may include touch I/O device 1001 that can receive touch input and force input (such as possibly including touch locations and applied force at those locations) for interacting with computing system 1003 (such as shown in the FIG. 1) via wired or wireless communication channel 1002. Touch I/O device 1001 may be used to provide user input to computing system 1003 in lieu of or in combination with other input devices such as a keyboard, mouse, or possibly other devices. In alternative embodiments, touch I/O device 1001 may be used in conjunction with other input devices, such as in addition to or in lieu of a mouse, trackpad, or possibly another pointing device. One or more touch I/O devices 1001 may be used for providing user input to computing system 1003. Touch I/O device 1001 may be an integral part of computing system 1003 (e.g., touch screen on a laptop) or may be separate from computing system 1003.

Touch I/O device 1001 may include a touch sensitive and force sensitive panel which is wholly or partially transparent, semitransparent, non-transparent, opaque or any combination thereof. Touch I/O device 1001 may be embodied as a touch screen, touch pad, a touch screen functioning as a touch pad (e.g., a touch screen replacing the touchpad of a laptop), a touch screen or touchpad combined or incorporated with any other input device (e.g., a touch screen or touchpad disposed on a keyboard, disposed on a trackpad or other pointing device), any multi-dimensional object having a touch sensitive surface for receiving touch input, or another type of input device or input/output device.

In one example, touch I/O device 1001 embodied as a touch screen may include a transparent and/or semitransparent touch sensitive and force sensitive panel at least partially or wholly positioned over at least a portion of a display. (Although the touch sensitive and force sensitive panel is described as at least partially or wholly positioned over at least a portion of a display, in alternative embodiments, at least a portion of circuitry or other elements used in embodiments of the touch sensitive and force sensitive panel may be at least positioned partially or wholly positioned under at least a portion of a display, interleaved with circuits used with at least a portion of a display, or otherwise.) According to this embodiment, touch I/O device 1001 functions to display graphical data transmitted from computing system 1003 (and/or another source) and also functions to receive user input. In other embodiments, touch I/O device 1001 may be embodied as an integrated touch screen where touch sensitive and force sensitive components/devices are integral with display components/devices. In still other embodiments a touch screen may be used as a supplemental or additional display screen for displaying supplemental or the same graphical data as a primary display and to receive touch input, including possibly touch locations and applied force at those locations.

Touch I/O device 1001 may be configured to detect the location of one or more touches or near touches on device 1001, and where applicable, force of those touches, based on capacitive, resistive, optical, acoustic, inductive, mechanical, chemical, or electromagnetic measurements, in lieu of or in combination or conjunction with any phenomena that can be measured with respect to the occurrences of the one or more touches or near touches, and where applicable, force of those touches, in proximity to device 1001. Software, hardware, firmware or any combination thereof may be used to process the measurements of the detected touches, and where applicable, force of those touches, to identify and track one or more gestures. A gesture may correspond to stationary or non-stationary, single or multiple, touches or near touches, and where applicable, force of those touches, on touch I/O device 1001. A gesture may be performed by moving one or more fingers or other objects in a particular manner on touch I/O device 1001 such as tapping, pressing, rocking, scrubbing, twisting, changing orientation, pressing with varying pressure and the like at essentially the same time, contiguously, consecutively, or otherwise. A gesture may be characterized by, but is not limited to a pinching, sliding, swiping, rotating, flexing, dragging, tapping, pushing and/or releasing, or other motion between or with any other finger or fingers, or any other portion of the body or other object. A single gesture may be performed with one or more hands, or any other portion of the body or other object by one or more users, or any combination thereof.

Computing system 1003 may drive a display with graphical data to display a graphical user interface (GUI). The GUI may be configured to receive touch input, and where applicable, force of that touch input, via touch I/O device 1001. Embodied as a touch screen, touch I/O device 1001 may display the GUI. Alternatively, the GUI may be displayed on a display separate from touch I/O device 1001. The GUI may include graphical elements displayed at particular locations within the interface. Graphical elements may include but are not limited to a variety of displayed virtual input devices including virtual scroll wheels, a virtual keyboard, virtual knobs or dials, virtual buttons, virtual levers, any virtual UI, and the like. A user may perform gestures at one or more particular locations on touch I/O device 1001 which may be associated with the graphical elements of the GUI. In other embodiments, the user may perform gestures at one or more locations that are independent of the locations of graphical elements of the GUI. Gestures performed on touch I/O device 1001 may directly or indirectly manipulate, control, modify, move, actuate, initiate or generally affect graphical elements such as cursors, icons, media files, lists, text, all or portions of images, or the like within the GUI. For instance, in the case of a touch screen, a user may directly interact with a graphical element by performing a gesture over the graphical element on the touch screen. Alternatively, a touch pad generally provides indirect interaction. Gestures may also affect non-displayed GUI elements (e.g., causing user interfaces to appear) or may affect other actions within computing system 1003 (e.g., affect a state or mode of a GUI, application, or operating system). Gestures may or may not be performed on touch I/O device 1001 in conjunction with a displayed cursor. For instance, in the case in which gestures are performed on a touchpad, a cursor (or pointer) may be displayed on a display screen or touch screen and the cursor may be controlled via touch input, and where applicable, force of that touch input, on the touchpad to interact with graphical objects on the display screen. In other embodiments in which gestures are performed directly on a touch screen, a user may interact directly with objects on the touch screen, with or without a cursor or pointer being displayed on the touch screen.

Feedback may be provided to the user via communication channel 1002 in response to or based on the touch or near touches, and where applicable, force of those touches, on touch I/O device 1001. Feedback may be transmitted optically, mechanically, electrically, olfactory, acoustically, haptically, or the like or any combination thereof and in a variable or non-variable manner.

Attention is now directed towards embodiments of a system architecture that may be embodied within any portable or non-portable device including but not limited to a communication device (e.g. mobile phone, smart phone), a multi-media device (e.g., MP3 player, TV, radio), a portable or handheld computer (e.g., tablet, netbook, laptop), a desktop computer, an All-In-One desktop, a peripheral device, or any other (portable or non-portable) system or device adaptable to the inclusion of system architecture 2000, including combinations of two or more of these types of devices. FIG. 2 is a block diagram of one embodiment of system 2000 that generally includes one or more computer-readable mediums 2001, processing system 2004, Input/Output (I/O) subsystem 2006, electromagnetic frequency circuitry, such as possibly radio frequency (RF) or other frequency circuitry 2008 and audio circuitry 2010. These components may be coupled by one or more communication buses or signal lines 2003. Each such bus or signal line may be denoted in the form 2003-X, where X can be a unique number. The bus or signal line may carry data of the appropriate type between components; each bus or signal line may differ from other buses/lines, but may perform generally similar operations.

It should be apparent that the architecture shown in FIGS. 1-2 is only one example architecture of system 2000, and that system 2000 could have more or fewer components than shown, or a different configuration of components. The various components shown in FIGS. 1-2 can be implemented in hardware, software, firmware or any combination thereof, including one or more signal processing and/or application specific integrated circuits.

RF circuitry 2008 is used to send and receive information over a wireless link or network to one or more other devices and includes well-known circuitry for performing this function. RF circuitry 2008 and audio circuitry 2010 are coupled to processing system 2004 via peripherals interface 2016. Interface 2016 includes various known components for establishing and maintaining communication between peripherals and processing system 2004. Audio circuitry 2010 is coupled to audio speaker 2050 and microphone 2052 and includes known circuitry for processing voice signals received from interface 2016 to enable a user to communicate in real-time with other users. In some embodiments, audio circuitry 2010 includes a headphone jack (not shown).

Peripherals interface 2016 couples the input and output peripherals of the system to processor 2018 and computer-readable medium 2001. One or more processors 2018 communicate with one or more computer-readable mediums 2001 via controller 2020. Computer-readable medium 2001 can be any device or medium that can store code and/or data for use by one or more processors 2018. Medium 2001 can include a memory hierarchy, including but not limited to cache, main memory and secondary memory. The memory hierarchy can be implemented using any combination of RAM (e.g., SRAM, DRAM, DDRAM), ROM, FLASH, magnetic and/or optical storage devices, such as disk drives, magnetic tape, CDs (compact disks) and DVDs (digital video discs). Medium 2001 may also include a transmission medium for carrying information-bearing signals indicative of computer instructions or data (with or without a carrier wave upon which the signals are modulated). For example, the transmission medium may include a communications network, including but not limited to the Internet (also referred to as the World Wide Web), intranet(s), Local Area Networks (LANs), Wide Local Area Networks (WLANs), Storage Area Networks (SANs), Metropolitan Area Networks (MAN) and the like.

One or more processors 2018 run various software components stored in medium 2001 to perform various functions for system 2000. In some embodiments, the software components include operating system 2022, communication module (or set of instructions) 2024, touch and applied force processing module (or set of instructions) 2026, graphics module (or set of instructions) 2028, one or more applications (or set of instructions) 2030, and fingerprint sensing module (or set of instructions) 2038. Each of these modules and above noted applications correspond to a set of instructions for performing one or more functions described above and the methods described in this application (e.g., the computer-implemented methods and other information processing methods described herein). These modules (i.e., sets of instructions) need not be implemented as separate software programs, procedures or modules, and thus various subsets of these modules may be combined or otherwise rearranged in various embodiments. In some embodiments, medium 2001 may store a subset of the modules and data structures identified above. Furthermore, medium 2001 may store additional modules and data structures not described above.

Operating system 2022 includes various procedures, sets of instructions, software components and/or drivers for controlling and managing general system tasks (e.g., memory management, storage device control, power management, etc.) and facilitates communication between various hardware and software components.

Communication module 2024 facilitates communication with other devices over one or more external ports 2036 or via RF circuitry 2008 and includes various software components for handling data received from RF circuitry 2008 and/or external port 2036.

Graphics module 2028 includes various known software components for rendering, animating and displaying graphical objects on a display surface. In embodiments in which touch I/O device 2012 is a touch sensitive and force sensitive display (e.g., touch screen), graphics module 2028 includes components for rendering, displaying, and animating objects on the touch sensitive and force sensitive display.

One or more applications 2030 can include any applications installed on system 2000, including without limitation, a browser, address book, contact list, email, instant messaging, word processing, keyboard emulation, widgets, JAVA-enabled applications, encryption, digital rights management, voice recognition, voice replication, location determination capability (such as that provided by the global positioning system, also sometimes referred to herein as “GPS”), a music player, and otherwise.

Touch and applied force processing module 2026 includes various software components for performing various tasks associated with touch I/O device 2012 including but not limited to receiving and processing touch input and applied force input received from I/O device 2012 via touch I/O device controller 2032.

System 2000 may further include fingerprint sensing module 2038 for performing the method/functions as described herein in connection with other figures shown and described herein.

I/O subsystem 2006 is coupled to touch I/O device 2012 and one or more other I/O devices 2014 for controlling or performing various functions. Touch I/O device 2012 communicates with processing system 2004 via touch I/O device controller 2032, which includes various components for processing user touch input and applied force input (e.g., scanning hardware). One or more other input controllers 2034 receives/sends electrical signals from/to other I/O devices 2014. Other I/O devices 2014 may include physical buttons, dials, slider switches, sticks, keyboards, touch pads, additional display screens, or any combination thereof.

If embodied as a touch screen, touch I/O device 2012 displays visual output to the user in a GUI. The visual output may include text, graphics, video, and any combination thereof. Some or all of the visual output may correspond to user-interface objects. Touch I/O device 2012 forms a touch-sensitive and force-sensitive surface that accepts touch input and applied force input from the user. Touch I/O device 2012 and touch screen controller 2032 (along with any associated modules and/or sets of instructions in medium 2001) detects and tracks touches or near touches, and where applicable, force of those touches (and any movement or release of the touch, and any change in the force of the touch) on touch I/O device 2012 and converts the detected touch input and applied force input into interaction with graphical objects, such as one or more user-interface objects. In the case in which device 2012 is embodied as a touch screen, the user can directly interact with graphical objects that are displayed on the touch screen. Alternatively, in the case in which device 2012 is embodied as a touch device other than a touch screen (e.g., a touch pad or trackpad), the user may indirectly interact with graphical objects that are displayed on a separate display screen embodied as I/O device 2014.

Touch I/O device 2012 may be analogous to the multi-touch sensitive surface described in the following U.S. Pat. No. 6,323,846 (Westerman et al.), U.S. Pat. No. 6,570,557 (Westerman et al.), and/or U.S. Pat. No. 6,677,932 (Westerman), and/or U.S. Patent Publication 2002/0015024A1, each of which is hereby incorporated by reference.

Embodiments in which touch I/O device 2012 is a touch screen, the touch screen may use LCD (liquid crystal display) technology, LPD (light emitting polymer display) technology, OLED (organic LED), or OEL (organic electro luminescence), although other display technologies may be used in other embodiments.

Feedback may be provided by touch I/O device 2012 based on the user's touch, and applied force, input as well as a state or states of what is being displayed and/or of the computing system. Feedback may be transmitted optically (e.g., light signal or displayed image), mechanically (e.g., haptic feedback, touch feedback, force feedback, or the like), electrically (e.g., electrical stimulation), olfactory, acoustically (e.g., beep or the like), or the like or any combination thereof and in a variable or non-variable manner.

System 2000 also includes power system 2044 for powering the various hardware components and may include a power management system, one or more power sources, a recharging system, a power failure detection circuit, a power converter or inverter, a power status indicator and any other components typically associated with the generation, management and distribution of power in portable devices.

In some embodiments, peripherals interface 2016, one or more processors 2018, and memory controller 2020 may be implemented on a single chip, such as processing system 2004. In some other embodiments, they may be implemented on separate chips.

Further System Elements

In one embodiment, an example system includes a force sensor coupled to the touch I/O device 2012, such as coupled to a force sensor controller. For example, the force sensor controller can be included in the I/O subsystem 2006. The force sensor controller can be coupled to a processor or other computing device, such as the processor 2018 or the secure processor 2040, with the effect that information from the force sensor controller can be measured, calculated, computed, or otherwise manipulated. In one embodiment, the force sensor can make use of one or more processors or other computing devices, coupled to or accessible to the touch I/O device 2012, such as the processor 2018, the secure processor 2040, or otherwise. In alternative embodiments, the force sensor can make use of one or more analog circuits or other specialized circuits, coupled to or accessible to the touch I/O device 2012, such as might be coupled to the I/O subsystem 2006.

In one embodiment, as described below, the force sensor determines a measure of applied force from a user contacting the touch I/O device 2012, such as in response to deflection in, or deformation of, a device stack. For example, as described herein, the force sensitive sensor can include a compressible layer, or a set of compressible elements, disposed between a set of organic light emitting diode (OLED) plastic display elements and the frame element. When the compressible layer or compressible elements are deflected or deformed, the force sensor can use capacitive sensing to determine an amount of deflection or deformation, with the effect of providing measurements of strain in response to applied force. Similarly, a touch sensor can use capacitive sensing in response to the compressible layer or compressible elements.

Example Force Sensor

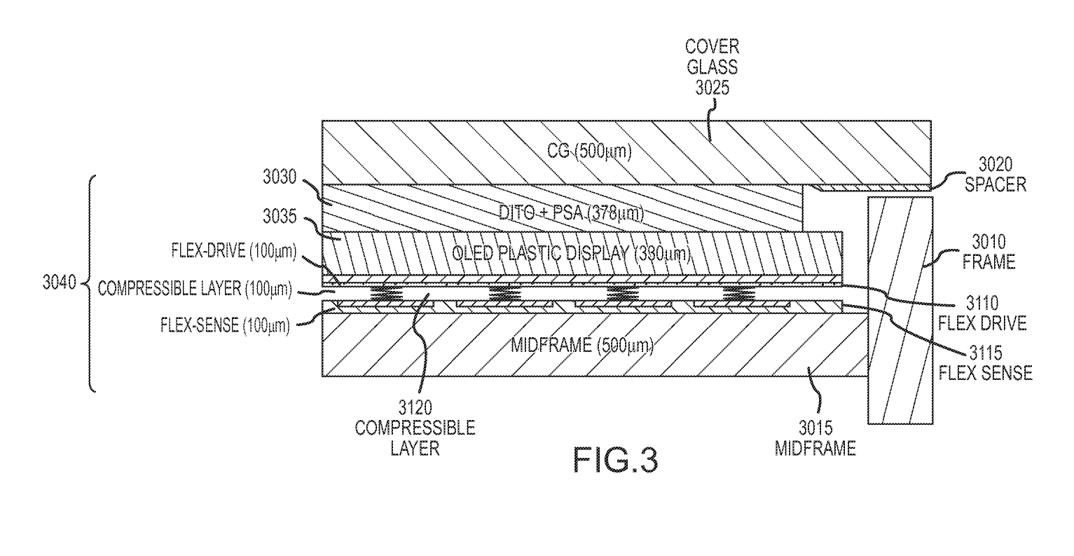

FIG. 3 shows a conceptual drawing of a force sensor including a dual-layer cover glass.

In one embodiment, the touch I/O device 2012 includes a frame 3010 and a midframe 3015 coupled to the frame 3010. The frame 3010 can be coupled to a spacer 3020, which is coupled to a cover glass (CG) 3025 and which can hold the cover glass (CG) 3025 substantially in place with respect to the frame 3010. In one embodiment, the cover glass (CG) 3025 can have approximately 500 microns of thickness.

In one embodiment, a device stack can be coupled below the cover glass (CG) 3025. In one embodiment, the touch I/O device 2012 can include a dual indium tin oxide (DITO) and pressure sensitive adhesive (PSA) layer 3030 positioned below the cover glass (CG) 3025. In one embodiment, the dual indium tin oxide (DITO) and pressure sensitive adhesive (PSA) layer 3030 can have approximately 378 microns of thickness. In one embodiment, the dual indium tin oxide (DITO) and pressure sensitive adhesive (PSA) layer 3030 can include multiple device element that are coupled in the device stack. Similarly, in one embodiment, an organic light emitting diode (OLED) plastic display element 3035 can be coupled below the dual indium tin oxide (DITO) and pressure sensitive adhesive (PSA) layer 3030. In one embodiment, the organic light emitting diode (OLED) plastic display element 3035 can have approximately 330 microns of thickness.

In one embodiment, the device stack can be coupled to a compressible construct 3040, which is responsive to deflection or deformation of the device stack in response to applied force by the user's finger. In one embodiment, the compressible construct 3040 is coupled to the midframe 3015. This has the effect that deflection or deformation of the device stack in response to applied force by the user's finger can cause compression of the compressible construct 3040, that compression being responsive to (A) applied force by the user's finger, and (B) resistance by the midframe 3015.

In one embodiment, the compressible construct 3040 includes a flex-drive layer 3110, such as a first printed conductive layer capable of carrying driver signals, a flex-sense layer 3115, such as a second printed conductive layer capable of carrying sensor signals, and a compressible layer 3120. In one embodiment, the flex-drive layer 3110 can have approximately 100 microns of thickness, the flex-sense layer 3115 can have approximately 100 microns of thickness, and the compressible layer 3120 can have approximately 100 microns of thickness.

As described herein, in one embodiment, the compressible construct 3040 can operate using capacitive sensing. In one embodiment, the flex-drive layer 3110 includes a set of drive signals. For example, the flex-drive layer 3110 can be disposed to include a set of columns, arranged to cover the entire cover glass. In one embodiment, each of the columns is electronically activated in turn, such as in a round-robin fashion, with the effect that each column is periodically activated, such as a relatively rapid rate. Similarly, the flex-sense layer 3115 can be disposed to include a set of rows, arranged cross-wise to the columns of the flex-drive layer 3110, and arranged to cover the entire cover glass. Similarly, in one embodiment, each of the rows is electronically sensed in turn, such as in a round-robin fashion, with the effect that each column is periodically sensed, such as a relatively rapid rate.

This has the effect that when applied force occurs at a particular point [X, Y] on the cover glass, the capacitive sensor measures a change in capacitance at one or more points near and around that point. As described herein, the device stack can be deformed near and around that point, with the effect that the entire cover glass undergoes a relative deformation and the applied force can be sensed substantially at most points in the device stack below the cover glass. While this application primarily describes a system in which two layers of ITO are used to detect a location of applied force using capacitance measurement between the two layers, in the context of the invention, there is no particular requirement for any such limitation. For example, capacitive sensing can be determined using a first layer of ITO as a self-capacitive element, with respect to a substantially conductive (such as metallic) second layer.

As described herein, in one embodiment, when the user applies force to the surface of the touch I/O device 2012, the device stack is deflected or deformed, with the effect that the compressible construct 3040 has force applied corresponding to the force applied to the surface of the touch I/O device 2012. This has the effect that the compressible layer 3120 is compressed, and the flex-drive layer 3110 is moved closer to the flex-sense layer 3115. When the force is no longer applied, the device stack releases the deflection or deformation, with the effect that the compressible construct 3040 no longer has force applied to it. This has the effect that the compressible layer 3120 is no longer compressed, and the flex-drive layer 3110 is moved back to its earlier position with respect to the flex-sense layer 3115. Accordingly, in one embodiment, the compressible layer 3120 is disposed to be relatively flexible and responsive to an applied force, and relatively flexible and substantially equally responsive to removal of that applied force.

In one embodiment, the compressible layer, or the set of compressible elements, can include a capacitive layer disposed between the first layer of ITO and the second layer of ITO. The capacitive layer can include an air gap, with the effect that capacitance is measured across the air gap. In one embodiment, the capacitive layer disposed between the first layer of ITO and the second layer of ITO can include a layer of pressure-sensitive adhesive (PSA), which can be either substantially transparent or translucent (if located above the OLED layer), or can alternatively be opaque or otherwise light-absorbent (if located below the OLED layer). In either such case, the capacitive layer has the effect of not interfering with operation of the display.

Force Image Construction

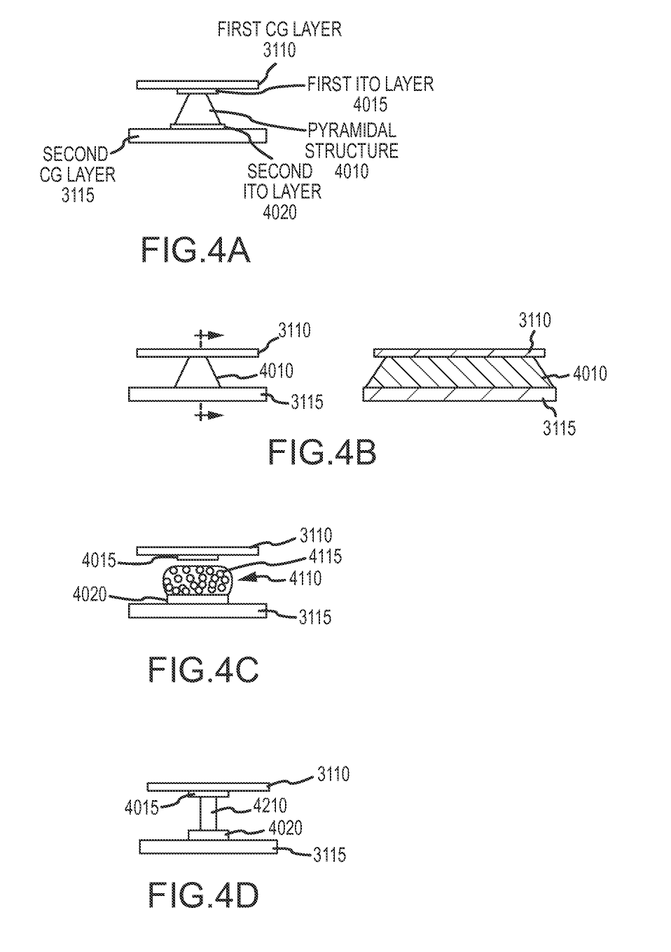

In one embodiment, the compressible layer, or the set of compressible elements, can include a set of strain gauges disposed in the compressible construct 3040, such as described below with respect to the FIGS. 4A-D. For example, a set of or compressible elements as described with respect to the FIGS. 4A-D can measure strain as the device stack is deflected or deformed. In such cases, the strain as the device stack is deflected or deformed can be distributed across the entire cover glass 3025, with the effect that strain can be measured at each location under the cover glass 3025, and at the edges of the cover glass 3025.

In response to a measure of strain at each location under the cover glass 3025, and at the edges of the cover glass 3025, the compressible layer 3120 can provide an image of applied force to each force sensing element with respect to the cover glass 3025, and at the edges of the cover glass 3025. In response to the image of applied force, the touch I/O device 2012 can determine a location [X, Y] of one or more particular points [X, Y] where applied force is occurring with respect to a surface of the cover glass 3025.

Force Sensitive Structures

FIGS. 4A-D show conceptual drawings of force sensitive structures.

In one embodiment, the compressible layer 3120 can include a first set of force sensitive structures. The force sensitive structures can include physical elements that are compressible, in addition to or instead of gels or liquids. These force sensitive structures can include features that are themselves compressible even if the material in which they are embedded, if there is a material in which they are embedded, is not otherwise compressible. This can have the effect that when force is applied to the CG construct 3020, that force is resisted by the force sensitive structures. In response to the resistance by the force sensitive structures, the touch I/O device can determine an amount of force being applied to the CG construct 3020.

In one embodiment, the force sensitive structures include compressible features relatively smaller than optical wavelengths. As described herein, this can have the effect that those compressible features can be substantially transparent, or otherwise not apparent to the user's eye when the user is applying force to the device, when the applied force is removed, or when the user is otherwise using the device.

In one embodiment, the force sensitive structures can be constructed using one or more of a set of possible construction techniques. For a first example, the structures can be constructed by etching voids into a relatively solid substance, such as silicon, a gel adhesive material, a composite material such as a nanoparticle-filled polymer, or otherwise. For a second example, the structures can be constructed by drilling elements into a relatively solid substance, such as silicon, or such as a gel adhesive material. For a third example, the structures can be constructed by drilling through-holes or vias into a relatively solid substance, such as silicon, or such as a gel adhesive material. For a fourth example, the structures can be constructed by growing elements from the flex-drive layer 3110 downward, similar to stalactites, or from the flex-sense layer 3115 upward, similar to stalagmites. For a fifth example, the structures can be constructed by an embossing or nanoimprint process, a photoresist process, or other methods.

In one embodiment, the force sensitive structures can be constructed with substantially empty space between the flex-drive layer 3110 and the flex-sense layer 3115, with the effect that the force sensitive structures absorb force applied between the flex-drive layer 3110 and the flex-sense layer 3115. In alternative embodiments, the force sensitive structures can be constructed with spaces between the elements of the force sensitive structures filled with a foam, a gel, a liquid, a springy or viscoelastic substance, a solid substance with a memory effect of returning to its original pre-deformation shape, or otherwise. For a first example, the spaces between the elements of the force sensitive structures can be filled with a nanofoam, that is, a foam with a set of nanopores, that is, nanostructure-sized holes disposed therein, with the effect that the nanofoam is capable of being compressed with a Poisson's ratio of less than about 0.48. For a second example, the spaces between the elements of the force sensitive structures can be filled with a set of micro-structured or nanostructured silicone elements, with the effect of being compressible in response to applied force, and also with the effect of returning to their original shape after the applied force is removed.

FIG. 4A shows a conceptual drawing of a set of pyramidal structures.

In one embodiment, the force sensitive structures can include a set of pyramidal rubber structures or pyramidal silicone structures (“nanostructures”) 4010, each of which can be positioned between the flex-drive layer 3110 and the flex-sense layer 3115. In the context of the invention, there are no particular requirements with respect to the sizes of the nanostructures. In a first such case, the nanostructures could be of substantially uniform size. In a second such case, the nanostructures could include nanostructures that are substantially of different sizes, such as including nanostructures of more than one size, or including nanostructures having a range of sizes. Moreover, in the context of the invention, there are no particular requirements with respect to the positioning of the nanostructures. In various possibilities, the nanostructures could be (A) positioned in a regular pattern; (B) positioned in random or pseudorandom locations; (C) positioned in some regions in one regular pattern and in other regions in a different regular pattern; (D) positioned in some regions in a regular pattern and in other regions in random or pseudorandom locations; or (E) some combination or conjunction thereof, or otherwise.

For example, pyramidal silicone structures 4010 can be positioned with the flex-sense layer 3115 at a bottom position. In such examples, positioned over the flex-sense layer 3115 can be a first circuit layer, such as the sense rows of the flex-sense layer 3115. In such examples, positioned over the sense rows of the flex-sense layer 3115 can be a base of the pyramidal silicone structures 4010. In such examples, positioned over the base of the pyramidal silicone structures 4010 can be the tip of the pyramidal silicone structures 4010, which can be a truncated tip (that is, a top of a truncated pyramid) or which can be a substantially non-truncated tip. In such examples, positioned over the tip of the pyramidal silicone structures 4010 can be a second circuit layer, such as the drive rows for the flex-drive layer 3110. In such examples, positioned over the second circuit layer can be the flex-drive layer 3110.

In alternative embodiments, the pyramidal rubber structures or pyramidal silicone structures 4010 can be inverted. In such cases, the base of the pyramidal structures 4010 can be at the top and can be coupled to the flex-drive layer 3110, while the tip of the pyramidal structures 4010 can be at the bottom and can be coupled to the flex-sense layer 3115. In other and further alternative embodiments, some of the pyramidal rubber structures or pyramidal silicone structures 4010 can be right side up while others can be inverted. In such cases, some of the pyramidal structures 4010 can be coupled at the base to the flex-drive layer 3110 and at the tip to the flex-sense layer 3115, while others can be coupled at the base to the flex-sense layer 3115 and at the tip to the flex-drive layer 3110. In other and further alternative embodiments, some or all of the pyramidal structures 4010 can be disposed with pairs with two bases, one coupled to the flex-drive layer 3110 and one to the flex-sense layer 3115, with the two tips of the pair meeting in a midpoint.

In one embodiment, the pyramidal rubber structures or pyramidal silicone structures 4010 can have a stiffness substantially equal to a value d², where d can be a parameter related to a capacitance of the substance used for the pyramidal structure 4010.

FIG. 4B shows a conceptual drawing of a set of elongated pyramidal structures.

In alternative embodiments, the pyramidal structure 4010 can be constructed in an elongated manner, with a cross-section that is pyramidal in a first direction, and is linear in a second direction. This has the effect that the pyramidal structure 4010 has a triangular shape when a cross-section is viewed across the structure 4010 along that first direction, and has a linear shape or a wall shape when a cross-section is viewed across the structure 4010 along that second direction. In one embodiment, the elongated pyramidal structures 4010 can have a stiffness substantially equal to a value d, where d can be a parameter related to a capacitance of the substance used for the pyramidal structure 4010.

FIG. 4C shows a conceptual drawing of a set of “moth eye” structures.

Similarly, in one embodiment, the force sensitive structures can include a set of “moth eye” structures 4110, each of which can have a base and a substantially hemispherical or near-hemispherical shape, and each of which can include a set of compound elements 4115, similar to the structure of a moth's eye. While this application primarily describes “moth eye” structures 4110 with particular shapes and orientations, in the context of the invention, there is no particular requirement for any such limitation. For a first example, the “moth eye” structures 4110 can include compound elements 4115 that are oriented substantially perpendicular to the base film. For a second example, the “moth eye” structures 4110 can include compound elements 4115 that have a density that decreases with increasing distance from the base film, that is, the compound elements 4115 are thick or dense near the base film, and are thinner or less dense with increasing distance away from the base film.

In such embodiments, similar to the pyramidal structures 4010, the moth eye structures 4110 can be coupled to the flex-drive layer 3110 and a first circuit layer at a top and to the flex-sense layer 3115 and a second circuit layer at a base. In alternative embodiments, similar to the pyramidal structures 4010, the moth eye structures 4110 can be inverted, and can be coupled to the flex-drive layer 3110 and a first circuit layer at a base and to the flex-sense layer 3115 and a second circuit layer at a top. In other and further alternative embodiments, similar to the pyramidal structures 4010, the moth eye structures 4110 can have some inverted and others non-inverted. In other and further alternative embodiments, similar to the pyramidal structures 4010, the moth eye structures 4110 can be disposed with pairs with two bases, one coupled to the flex-drive layer 3110 and one to the flex-sense layer 3115, with the two tips of the pair meeting in a midpoint.

FIG. 4D shows a conceptual drawing of a set of cylindrical structures.

Similarly, in one embodiment, the force sensitive structures can include a set of cylindrical structures 4210, each of which can have a base and a tip, and a substantially cylindrical (or polygonal) cross-section. In such embodiments, similar to the pyramidal structures 4010, the cylindrical structures 4210 can be coupled to the flex-drive layer 3110 and a first circuit layer at a top and to the flex-sense layer 3115 and a second circuit layer at a base. In such embodiments, the cylindrical structures 4210 can include elements or substances to optimize their relative stiffness independent of a value d, where d can be a parameter related to a capacitance of the substance used for the structure. For example, cylindrical structures can have their stiffness tuned with respect to the parameter d, such as using angles, shapes, or auxiliary structures.

### ALTERNATIVE EMBODIMENTS

After reading this application, those skilled in the art would recognize that techniques for obtaining information with respect to applied force and contact on a touch I/O device, and using that associated information to determine amounts and locations of applied force and contact on a touch I/O device, is responsive to, and transformative of, real-world data such as relative capacitance and compressibility received from applied force or contact by a user's finger, and provides a useful and tangible result in the service of detecting and using applied force and contact with a touch I/O device. Moreover, after reading this application, those skilled in the art would recognize that processing of applied force and contact sensor information by a computing device includes substantial computer control and programming, involves substantial records of applied force and contact sensor information, and involves interaction with applied force and contact sensor hardware and optionally a user interface for use of applied force and contact sensor information.

Certain aspects of the embodiments described in the present disclosure may be provided as a computer program product, or software, that may include, for example, a computer-readable storage medium or a non-transitory machine-readable medium having stored thereon instructions, which may be used to program a computer system (or other electronic devices) to perform a process according to the present disclosure. A non-transitory machine-readable medium includes any mechanism for storing information in a form (e.g., software, processing application) readable by a machine (e.g., a computer). The non-transitory machine-readable medium may take the form of, but is not limited to, a magnetic storage medium (e.g., floppy diskette, video cassette, and so on); optical storage medium (e.g., CD-ROM); magneto-optical storage medium; read only memory (ROM); random access memory (RAM); erasable programmable memory (e.g., EPROM and EEPROM); flash memory; and so on.

While the present disclosure has been described with reference to various embodiments, it will be understood that these embodiments are illustrative and that the scope of the disclosure is not limited to them. Many variations, modifications, additions, and improvements are possible. More generally, embodiments in accordance with the present disclosure have been described in the context of particular embodiments. Functionality may be separated or combined in procedures differently in various embodiments of the disclosure or described with different terminology. These and other variations, modifications, additions, and improvements may fall within the scope of the disclosure as defined in the claims that follow.

1. Apparatus including
a touch device including one or more applied force sensors, said applied force sensors including
a deformable device stack;
a frame element;
a compressible layer positioned in between said device stack and said frame element, said compressible layer including one or more force sensitive elements;
wherein said touch device is responsive to said force sensitive elements, and capable of determining an amount and location of applied force on a surface of said touch device.

2. Apparatus as in claim 1, wherein
said compressible layer includes a compressible structure, said compressible structure being substantially solid and having compressible elements, said compressible elements being substantially smaller than an optical wavelength.

3. Apparatus as in claim 1, wherein
said compressible layer includes a compressible structure, said compressible structure being substantially solid and having compressible elements, said compressible elements having a compression resistance substantially linear in compression with respect to a compression parameter.

4. Apparatus as in claim 1, wherein
said compressible layer includes a compressible structure, said compressible structure being substantially solid and having compressible elements, said compressible elements having a compression resistance substantially polynomial in compression with respect to a compression parameter.

5. Apparatus as in claim 1, wherein
said compressible layer includes one or more of:
a solid compressible element, said solid compressible element including one or more of:
a cylindrical silicone element, a moth eye element, a nanopore element, a pyramidal silicone element.

6. Apparatus as in claim 1, wherein
said compressible layer is positioned between an LED display element and said frame element.

7. Apparatus as in claim 1, wherein
said touch device includes one or more touch sensors,
wherein said touch device is responsive to said touch sensors, and capable of determining a touch location on a surface of said touch device.

8. Apparatus as in claim 1, wherein
said compressible layer includes one or more capacitive sensors;
said touch device is responsive to said capacitive sensors, and capable of determining an amount and location of applied force in response to said capacitive sensors.

9. Apparatus as in claim 8, wherein
in response to said strain gauges, said touch device determining an image of applied force applicable to at least a region of a surface of said touch device.

10. Apparatus as in claim 8, wherein
said capacitive sensors include
a first circuit layer including an element capable of coupling a drive signal to said capacitive sensors, and
a second circuit layer including an element capable of coupling a sense signal from said capacitive sensors.

11. Apparatus as in claim 1, wherein
said compressible layer includes one or more of:
a foam, a gel, a liquid, an optically translucent or transparent substance.

12. Apparatus as in claim 11, wherein
said compressible layer includes a substance having a Poisson's ratio of less than approximately 0.48.

13. Apparatus as in claim 1, wherein
said compressible layer includes one or more strain gauges;
said touch device is responsive to said strain gauges, and capable of determining an amount and location of applied force in response to said strain gauges.

14. Apparatus as in claim 13, wherein
in response to said strain gauges, said touch device determining an image of applied force applicable to at least a region of a surface of said touch device.

15. Apparatus as in claim 13, wherein
said strain gauges are responsive to a measure of tilt on said surface of said touch device.

16. A touch device including
one or more applied force sensors, said applied force sensors including
a deformable device stack;
a compressible layer positioned in between said device stack and a substantially rigid element positioned below said device stack, said compressible layer including one or more force sensitive elements;
one or more capacitive touch sensing elements;
wherein said touch device capable of determining an amount and location of applied force on a surface thereof in response to said force sensitive elements and said touch sensing elements.

17. A touch device as in claim 16, wherein
said applied force sensors are responsive to a measure of compression of said compressible layer.

18. A touch device as in claim 16, wherein
said applied force sensors are responsive to a measure of deformation of said device stack.

19. A touch device as in claim 16, wherein
said compressible layer includes at least one nanostructure having a first size and at least one nanostructure having a second size.

20. A touch device as in claim 16, wherein
said compressible layer includes one or more nanostructures having a density that varies with a distance from a substrate.

21. A touch device as in claim 16, wherein
said compressible layer includes one or more of:
a set of nanostructures positioned in a regular pattern, a set of nanostructures positioned in a set of random or pseudorandom locations.

22. A touch device as in claim 16, wherein
said compressible layer includes
a set of nanostructures positioned in a regular pattern, and
a set of nanostructures positioned in a set of random or pseudorandom locations.

23. A touch device as in claim 16, wherein
said compressible layer includes one or more of:
one or more relatively open elements, one or more relatively compressible solid elements.

24. A touch device as in claim 16, wherein
said compressible layer includes a network of: one or more relatively open elements, and one or more relatively compressible solid elements.

25. A touch device as in claim 16, wherein
said touch device includes a substantially flexible display element positioned above said compressible layer.

26. A touch device as in claim 25, wherein
said substantially flexible display element includes one or more of:
an electrochromic display, an electrofluidic display, an electrokinetic display, an electrophoretic display, a liquid crystal display, a polymer display, a polymer dispersed liquid crystal display, a polymer network liquid crystal display, a microencapsulated cholesteric liquid crystal display.

27. A method, including steps of
determining a measure of applied force on a touch device, in response to one or more force sensitive elements positioned in a compressible layer, said compressible layer being positioned between a deformable device stack and a frame element; and
determining a location of said applied force in response to said force sensitive elements.

28. A method as in claim 27, including steps of
measuring a compression resistance of said compressible layer;
wherein said compression resistance is substantially linear in compression with respect to a compression parameter.

29. A method as in claim 27, including steps of
measuring a compression resistance of said compressible layer;
wherein said compression resistance is substantially nonlinear in compression with respect to a compression parameter.

30. A method as in claim 27, including steps of
determining a touch location on a surface of said touch device in response to one or more touch sensors.

31. A method as in claim 27, including steps of
measuring a capacitance in response to said compressible layer; and
determining an amount and location of applied force in response to said stesps of measuring a capacitance.

32. A method as in claim 27, wherein
determining an image of applied force applicable to at least a region of a surface of said touch device.

33. A method of operating a touch device, said method including steps of
determining an amount and location of applied force on a surface of said touch device, in response to one or more force sensitive elements and one or more touch sensing elements;
wherein said force sensitive elements are disposed in a compressible layer positioned in between a substantially deformable device stack and a substantially rigid element positioned below said device stack; and
wherein said touch sensing elements include one or more capacitors.

34. A method of operating a touch device as in claim 33, including steps of
operating a substantially flexible display element positioned above said compressible layer.

35. A method of operating a touch device as in claim 34, wherein
said substantially flexible display element includes one or more of:
an electrochromic display, an electrofluidic display, an electrokinetic display, an electrophoretic display, a liquid crystal display, a polymer display, a polymer dispersed liquid crystal display, a polymer network liquid crystal display, a microencapsulated cholesteric liquid crystal display.
